(19) United States
(12) Patent Application Publication
(10) Pub. No.: US 2026/0206338 A1
(43) Pub. Date: Jul. 16, 2026

(54) SEMICONDUCTOR DETECTOR, MANUFACTURING METHOD THEREOF, AND DETECTING METHOD USING THE SAME

(71) Applicants: TAIWAN SEMICONDUCTOR MANUFACTURING COMPANY, LTD., Hsinchu (TW); NATIONAL TSING HUA UNIVERSITY, HSINCHU CITY (TW)

(72) Inventors: Ya-Chin KING, Taipei City (TW); Chrong Jung LIN, Hsinchu City (TW); Burn Jeng LIN, Hsinchu City (TW); Wei CHANG, New Taipei City (TW)

(73) Assignees: TAIWAN SEMICONDUCTOR MANUFACTURING COMPANY, LTD., Hsinchu (TW); NATIONAL TSING HUA UNIVERSITY, HSINCHU CITY (TW)

(21) Appl. No.: 19/022,759

(22) Filed: Jan. 15, 2025

(51) Int. Cl. H10F 39/10; G01J 1/42; G01J 1/44

(52) U.S. Cl. CPC H10F 39/103; G01J 1/429; G01J 1/44; G01J 2001/446

(57) ABSTRACT

A device includes a substrate, a first recording unit, and a second recording unit. The first recording unit is over the substrate and includes a first active region over the substrate, a first gate structure over the first active region, a first sensing contact adjacent to the first gate structure, and a first sensing pad over and electrically connected to the first sensing contact. The second recording unit is over the substrate and includes a second active region over the substrate, a second gate structure over the second active region, a second sensing contact adjacent to the second gate structure, and a second sensing pad over and electrically connected to the second sensing contact. The first and the second recording unit are arranged in a first direction, and the second sensing pad has a length greater than a length of the first sensing pad in a second direction.

### BACKGROUND

The semiconductor integrated circuit industry has experienced rapid growth in the past several decades. Technological advances in semiconductor materials and design have produced increasingly smaller and more complex circuits. These material and design advances have been made possible as the technologies related to processing and manufacturing have also undergone technical advances. In the course of semiconductor evolution, the number of interconnected devices per unit of area has increased as the size of the smallest component that can be reliably created has decreased.

As the size has decreased, maintaining the reliability in patterning processes and the yields produced by the patterning processes has become more difficult. In some cases, the use of optical proximity correction and the adjustment of lithography parameters such as the duration of a process, the wavelength, focus, and intensity of light used can mitigate some defects. However, the current and systems for patterning material layers in semiconductor wafers has not been entirely satisfactory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor detector in accordance with some embodiments.

FIG. 2 is a layout diagram of the semiconductor detector in FIG. 1 in accordance with some embodiments.

FIG. 3 is a schematic cross-sectional view of the semiconductor detector in FIG. 1 in accordance with some embodiments.

FIG. 4 is a schematic circuit diagram illustrating the semiconductor detector of FIG. 1 according to some embodiments of the present disclosure.

FIG. 5 is a schematic circuit diagram illustrating a semiconductor detector according to some embodiments of the present disclosure.

FIG. 6 is a schematic partial top view of the semiconductor detector in accordance with some embodiments.

FIG. 7 is another schematic partial top view of the semiconductor detector in accordance with some embodiments.

FIG. 8 is a flowchart of a method for in-situ detecting light uniformity of e-beam according to aspects of the present disclosure in various embodiments.

FIG. 9 is a schematic circuit diagram of a semiconductor device including a semiconductor detector in FIG. 5 in accordance with some embodiments.

FIG. 10A is a perspective view of sensing pads in accordance with some embodiments.

FIG. 10B is amounts of floating gate charge (Q_{FG}) corresponding to the sensing pads in the post-exposure reading.

FIG. 10C is a spectrum of differential signals in the X direction.

FIG. 11 is an experimental mapping image of threshold voltage shifts of the recording units under different EUV exposure inputs.

FIG. 12 is a mapping image of readout EUV dosage distribution in the X direction under different EUV exposure inputs.

FIGS. 13-16 illustrate a method for manufacturing the semiconductor detector 10a at various stages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

The present disclosure is related to semiconductor detectors, methods of forming the same, and methods of using the same. More particularly, some embodiments of the present disclosure are related to high-spatial-resolution and powerless-sensing semiconductor detectors for detecting e-beam (e.g., EUV, DUV, etc) lights. In some embodiments, the semiconductor detectors may be realized on the device including planar devices, multi-gate devices, FinFETs, nanosheet-gate FETs, and gate-all-around FETs.

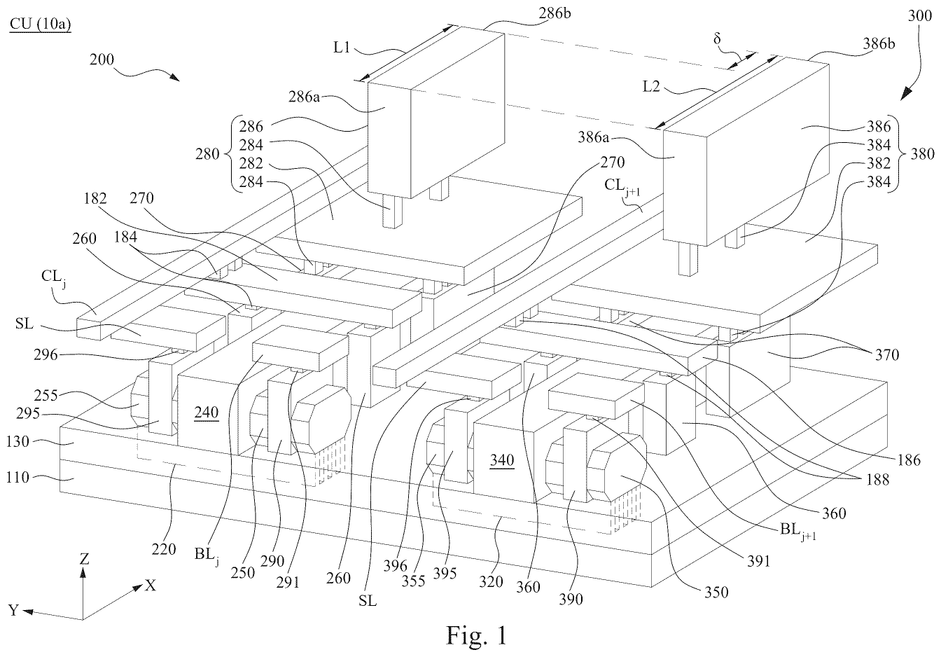

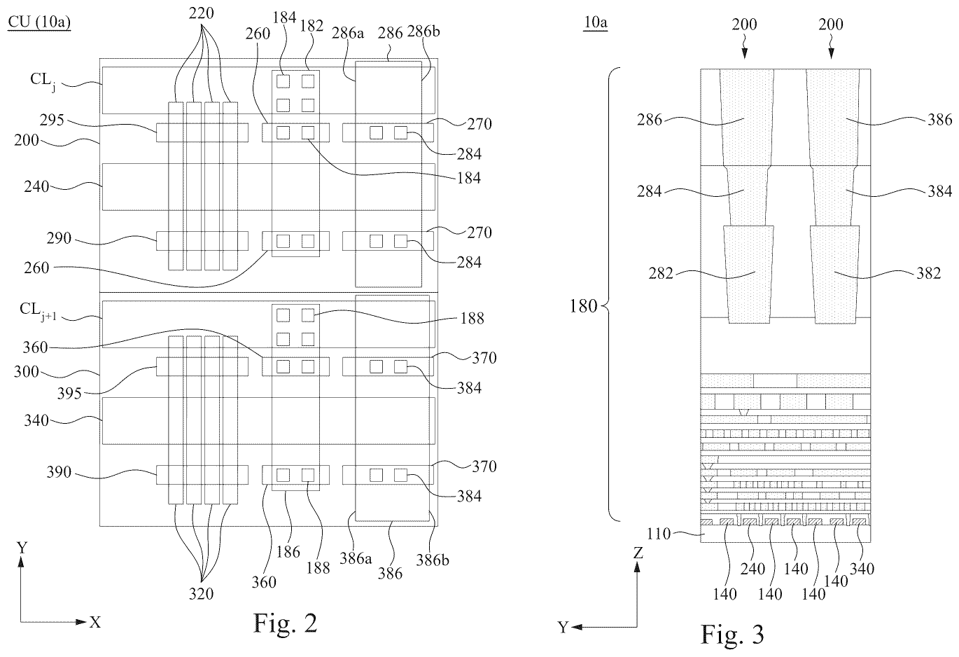

FIG. 1 is a perspective view of a semiconductor detector 10a in accordance with some embodiments, and FIG. 2 is a layout diagram of the semiconductor detector 10a in FIG. 1 in accordance with some embodiments. The semiconductor detector 10a in FIGS. 1 and 2 includes a single cell unit CU. The (cell unit CU of the) semiconductor detector 10a includes a substrate 110, a first recording unit 200, and a second recording unit 300. The first recording unit 200 and the second recording unit 300 are over the substrate 110. The first recording unit 200 includes at least one active region, a gate structure 240, a first source/drain epitaxial structure 250, a second source/drain epitaxial structure 255, at least one reading contact 260, at least one sensing contact 270, and a sensing pad structure 280. The active region may be a semiconductor fin 220 protruding from the substrate 110. It is noted that although there are four semiconductor fins 220 in FIGS. 1 and 2, the claimed scope of the present disclosure is not limited in this respect. In some other embodiments, a person having ordinary skill in the art can manufacture suitable number of the semiconductor fins 220 of the semiconductor detector 10a according to actual situations.

The (cell unit CU of the) semiconductor detector 10a further includes an isolation structure 130 over the substrate 110 and laterally surrounds the semiconductor fins 220. That is, bottom portions of the semiconductor fins 220 are embedded in the isolation structure 130. The isolation structure 130 may be shallow trench isolation (STI) regions.

The gate structure 240 is over the isolation structure 130 and crosses the semiconductor fins 220. Portions of the semiconductor fins 220 covered by the gate structure 240 are referred to as channel portions of the semiconductor fins 220. In some embodiments, there is no electrically conductive element physically connected to the gate structure 240, such that the gate structure 240 can be referred to as a floating gate.

The first source/drain epitaxial structure 250 and the second source/drain epitaxial structure 255 are over the semiconductor fins 220 and are on opposite sides of the gate structure 240. As such, one of the first source/drain epitaxial structure 250 and the second source/drain epitaxial structure 255 serves as a source terminal and another one of the first source/drain epitaxial structure 250 and the second source/drain epitaxial structure 255 serves as a drain terminal. Portions of the semiconductor fins 220 under the first source/drain epitaxial structure 250 and portions of the semiconductor fins 220 under the second source/drain epitaxial structure 255 are referred to as source/drain portions of the semiconductor fins 220. The gate structure 240, the semiconductor fins 220, the first source/drain epitaxial structure 250, and the second source/drain epitaxial structure 255 form a transistor with the floating gate used as a signal storage node.

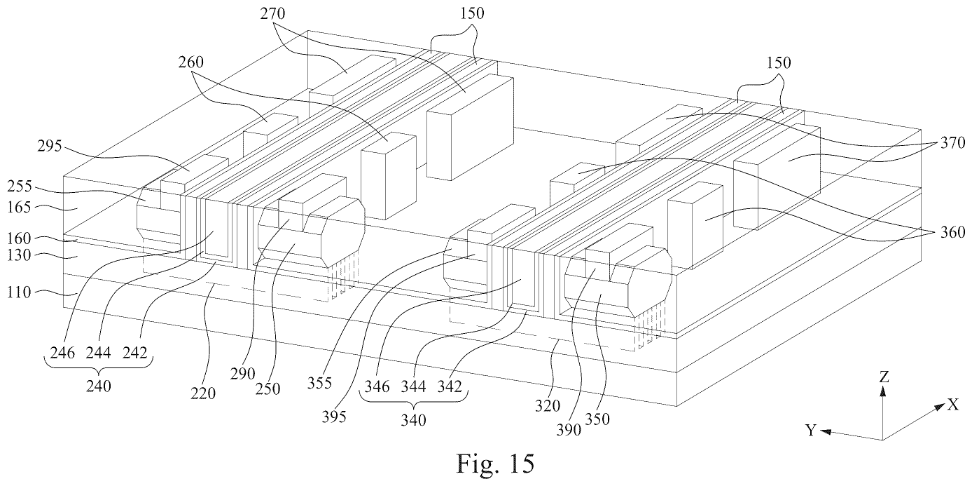

Two reading contacts 260 are adjacent to the gate structure 240 and directly on the isolation structure 130, such that the two reading contacts 260 are spaced apart from the semiconductor fins 220. The reading contacts 260 are on opposite sides of the gate structure 240 and are further spaced apart from the first source/drain epitaxial structure 250 and the second source/drain epitaxial structure 255. The reading contacts 260 are separated from the gate structure 240 by a dielectric material (e.g., the gate spacers 150, the CESL 160, and/or the ILD layer 165 in FIG. 15). As such, the gate structure 240, the reading contact 260, and the dielectric material therebetween form a capacitance. In some embodiments, the first recording unit 200 includes a single reading contact 260 on one side of the gate structure 240.

Two sensing contacts 270 are adjacent to the gate structure 240 and directly on the isolation structure 130, such that the two sensing contacts 270 are spaced apart from the semiconductor fins 220. The sensing contacts 270 are on opposite sides of the gate structure 240 and are further spaced apart from the first source/drain epitaxial structure 250 and the second source/drain epitaxial structure 255. In some embodiments, the sensing contact 270 and the reading contact 260 are on the same sides of the first source/drain epitaxial structure 250 (and/or the second source/drain epitaxial structure 255). That is, the reading contact 260 is between the sensing contact 270 and the semiconductor fins 220. The sensing contacts 270 are separated from the gate structure 240 by a dielectric material (e.g., the gate spacers 150, the CESL 160, and/or the ILD layer 165 in FIG. 15). As such, the gate structure 240, the sensing contact 270, and the dielectric material therebetween form a capacitance. In some embodiments, the first recording unit 200 includes a single sensing contact 270 on one side of the gate structure 240. Moreover, the isolation structure 130 is in contact with the reading contacts 260, the sensing contacts 270, and the semiconductor fins 220.

The sensing pad structure 280 is electrically connected to the sensing contacts 270. In some embodiments, the sensing pad structure 280 is disposed over the sensing contacts 270 and the gate structure 240. In some embodiments, the sensing pad structure 280 includes a plurality of conductive pads 282 and conductive vias 284 between adjacent conductive pads 282. Some of the conductive vias 284 interconnect adjacent conductive pads 282, and some of the conductive vias 284 interconnect the bottommost conductive pad 282 and the sensing contacts 270. The conductive pads 282 and the conductive vias 284 are conductive materials, such that electrons can flow from the conductive pads 282 to the sensing contacts 270. Further, a capacitance can be formed between the bottommost conductive pad 282 and the gate structure 240 if the bottommost conductive pad 282 is close enough to the gate structure 240.

The sensing pad structure 280 further includes a sensing pad 286, which is electrically connected to the sensing contacts 270 through the conductive vias 284 and the conductive pads 282. The sensing pad 286 may be at the topmost level (e.g., Mn level) of the sensing pad structure 280 to guarantee accuracy during EUV/DUV detection.

The second recording unit 300 has a similar structural configuration to the first recording unit 200 except the configuration of a sensing pad 386 of a sensing pad structure 380 of the second recording unit 300. That is, the second recording unit 300 includes at least one active region, a gate structure 340, a first source/drain epitaxial structure 350, a second source/drain epitaxial structure 355, at least one reading contact 360, at least one sensing contact 370, and the sensing pad structure 380. The active region may be semiconductor fins 320 protruding from the substrate 110, and the isolation structure 130 laterally surrounds the semiconductor fins 320. That is, bottom portions of the semiconductor fins 320 are embedded in the isolation structure 130. It is noted that although there are four semiconductor fins 320 in FIGS. 1 and 2, the claimed scope of the present disclosure is not limited in this respect. In some other embodiments, a person having ordinary skill in the art can manufacture suitable number of the semiconductor fins 320 of the semiconductor detector 10a according to actual situations. The gate structure 340, the semiconductor fins 320, the first source/drain epitaxial structure 350, and the second source/drain epitaxial structure 355 form a transistor with the floating gate used as a signal storage node.

The sensing pad structure 380 includes conductive pads 382, conductive vias 384, and the sensing pad 386. The structural configurations of the semiconductor fins 320, the gate structure 340, the first source/drain epitaxial structure 350, the second source/drain epitaxial structure 355, the reading contact 360, the sensing contact 370, and the sensing pad structure 380 are similar to the semiconductor fins 220, the gate structure 240, the first source/drain epitaxial structure 250, the second source/drain epitaxial structure 255, the reading contact 260, the sensing contact 270, and the sensing pad structure 280, respectively. Therefore, a description in this regard will not be repeated hereinafter.

The first recording unit 200 and the second recording unit 300 are arranged along a first direction (e.g., Y direction in this case). The sensing pads 286 and 386 have different lengths. Specifically, the sensing pad 286 has a length L1 in the second direction (e.g., X direction in this case) substantially perpendicular to the first direction, and the sensing pad 386 has a length L2 in the second direction. The length L2 of the sensing pad 386 is greater than the length L1 of the sensing pad 286 by a distance δ. Further, the sensing pad 286 has a first end 286a and a second end 286b opposite to the first end 286a in the second direction, and the sensing pad 386 has a first end 386a and a second end 386b opposite to the first end 386a. The first end 286a of the sensing pad 286 is substantially aligned with the first end 386a of the sensing pad 386 in the first direction, and the second end 286b of the sensing pad 286 is misaligned with the second end 386b of the sensing pad 386 in the first direction. With such structural configuration, the spatial resolution of the cell unit CU of the semiconductor detector 10a can achieve nanometer (e.g., the order of the distance δ) precision when employing micrometer-sized (e.g., the order of the lengths L1 and L2) structures as sensing pads.

In some embodiments, the distance δ is in a range of about 28 nm to about 50 μm. If the distance δ is less than about 28 nm, the differential signal between the first recording unit 200 and the second recording unit 300 may be not disclosed. In some embodiments, the value of the distance δ is smaller than the value of the length L1. It is noted that in some embodiments, the distance δ is greater than about 50 μm according to the desired resolution of the cell unit CU. In some embodiments, each of the lengths L1 and L2 is in a range of about 0.1 μm to about 70 μm. Further, the width of each of the sensing pads 286 and 386 is in a range of about 0.1 μm to about 70 μm. It is noted that in some embodiments, the lengths L1 and L2 and/or the widths of the sensing pads 286 and 386 are greater than about 70 μm (e.g., up to centimeter scales) according to the desired device size of the cell unit CU.

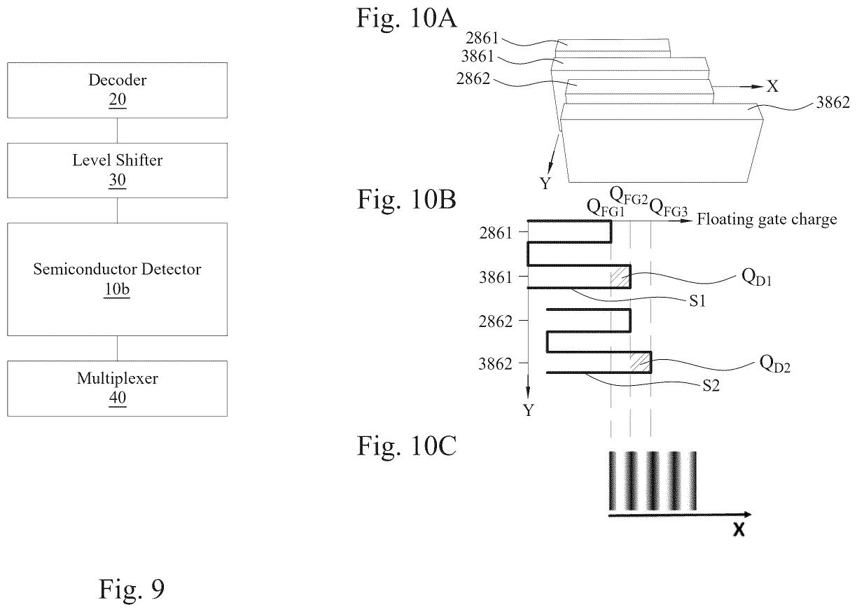

FIG. 3 is a schematic cross-sectional view of the semiconductor detector 10a in FIG. 1 in accordance with some embodiments. In some embodiments, the semiconductor detector 10a further includes a plurality of dummy gate structures 140 between the gate structures 240 and 340. The dummy gate structures 140 may have no functionality in the semiconductor detector 10a but make the device processes more uniform, more reproducible, and more manufacturable. The semiconductor detector 10a may further include an interconnect structure 180 over the gate structures 240, 340 and the dummy gate structures 140. The sensing pad structures 280 and 380 (see FIG. 1) are embedded in the interconnect structure 180. Further, peripheral circuits (e.g., a decoder 20, a level shifter 30, and a multiplexer 40 in FIG. 9) connected to the semiconductor detector 10a may also be partially or entirely embedded in the interconnect structure 180.

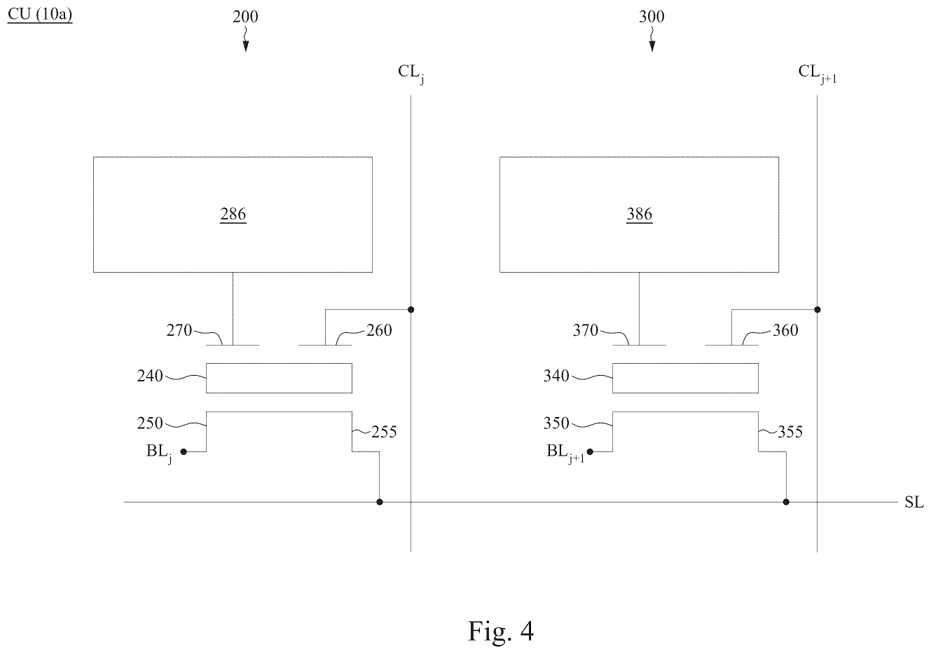

FIG. 4 is a schematic circuit diagram illustrating the semiconductor detector 10a of FIG. 1 according to some embodiments of the present disclosure. Reference is made to FIGS. 1-2 and 4. The (cell unit CU of the) semiconductor detector 10a further includes column lines CLⱼ and CLⱼ₊₁ and bit lines BLⱼ and BLⱼ₊₁. The column lines CLⱼ and CLⱼ₊₁ are electrically connected to the reading contacts 260 and 360, respectively. For example, in FIGS. 1 and 2, the column line CLⱼ is electrically connected to the reading contacts 260 through a conductive line 182 and conductive vias 184, and the column line CLⱼ₊₁ is electrically connected to the reading contacts 360 through a conductive line 186 and conductive vias 188. The bit lines BLⱼ and BLⱼ₊₁ are electrically connected to the first source/drain epitaxial structures 250 and 350 (e.g., the drain of the cell unit CU), respectively. For example, the bit lines BLⱼ and BLⱼ₊₁ are connected to the first source/drain epitaxial structures 250 and 350 through source/drain contacts 290 and 390, respectively, and conductive vias 291 and 391, respectively. Further, the column line CLⱼ is electrically isolated from the gate structure 240, and the column line CLⱼ₊₁ is electrically isolated from the gate structure 340. In some embodiments, the second source/drain epitaxial structure 255 and 355 are electrically connected to a source line SL, which provides a reference electrical potential to the semiconductor detector 10a during programming, erasing, and/or reading processes, through source/drain contacts 295 and 395 and conductive vias 296 and 396.

The (cell unit CU of the) semiconductor detector 10a has four different states it can be in: programming, erasing, sensing, and reading. The semiconductor detector 10a performs the four different states (program, erase, sense, and read) as follows:
Programming—In some embodiments, the start of a program cycle of the semiconductor detector 10a begins by applying a positive voltage to the column lines CLⱼ and CLⱼ₊₁ and applying a negative voltage to the bit lines BLⱼ and BLⱼ₊₁. Further, the second source/drain epitaxial structures 255 and 355 are connected to the source line SL. As such, the gate structures 240 and 340 are floating and electric fields are formed in the gate structures 240 and 340, driving electrons to flow from the substrate 110 to the gate structures 240 and 340 through tunneling effect, and the electrons can be stored in the gate structures 240 and 340.

Erasing—In some embodiments, the start of an erase cycle of the semiconductor detector 10a begins by baking the semiconductor detector 10a. For example, the wafer including the semiconductor detector 10a can be performed with a thermal process. By heating the semiconductor detector 10 a at a temperature in a range of about 200° C. to about 300° C. for a few days, the amounts of the electrons in the gate structures 240 and 340 can be uniform, and the gate structures 240 and 340 have substantially the same electric potential. As such, the first recording unit 200 and the second recording unit 300 have substantially the same initial condition for sensing the dosage of EUV/DUV light.

In some other embodiments, the start of an erase cycle of the semiconductor detector 10a begins by applying a negative voltage to the column lines CLⱼ and CLⱼ₊₁ and applying a positive voltage to the bit lines BLⱼ and BLⱼ₊₁. Further, the second source/drain epitaxial structures 255 and 355 are connected to the source line SL. As such, the gate structures 240 and 340 are floating and electric field are formed in the gate structures 240 and 340, driving electrons to flow from the gate structures 240 and 340 to the substrate 110 through tunneling effect, and the gate structures 240 and 340 are supposed to be free of electrons.

Sensing—During the sense cycle of the semiconductor detector 10a, no power is applied to the column lines CLⱼ and CLⱼ₊₁, the bit lines BLⱼ and BLⱼ₊₁, and the second source/drain epitaxial structures 255 and 355. In other word, the semiconductor detector 10a is powerless (or battery-less) in the sensing mode. When e-beam light is incident on the sensing pad structures 280 and 380, electrons of the e-beam light enter the sensing pads 286 and 386 of the sensing pad structures 280 and 380 and flow to the sensing contacts 270 and 370, respectively. An electrical coupling is formed between the sensing contact(s) 270 and the gate structure 240 while an electrical coupling is formed between the sensing contact(s) 370 and the gate structure 340, and the electric potentials in the gate structures 240 and 340 are changed.

Reading—The start of a read cycle of the semiconductor detector 10a begins by applying a varied positive voltage to the column lines CLⱼ and CLⱼ₊₁, applying a reference electrical potential to the second source/drain epitaxial structures 255 and 355, and the gate structures 240 and 340 are floating, such that a corresponding current under the varied positive voltage are read from each of the bit lines BLⱼ and BLⱼ₊₁.

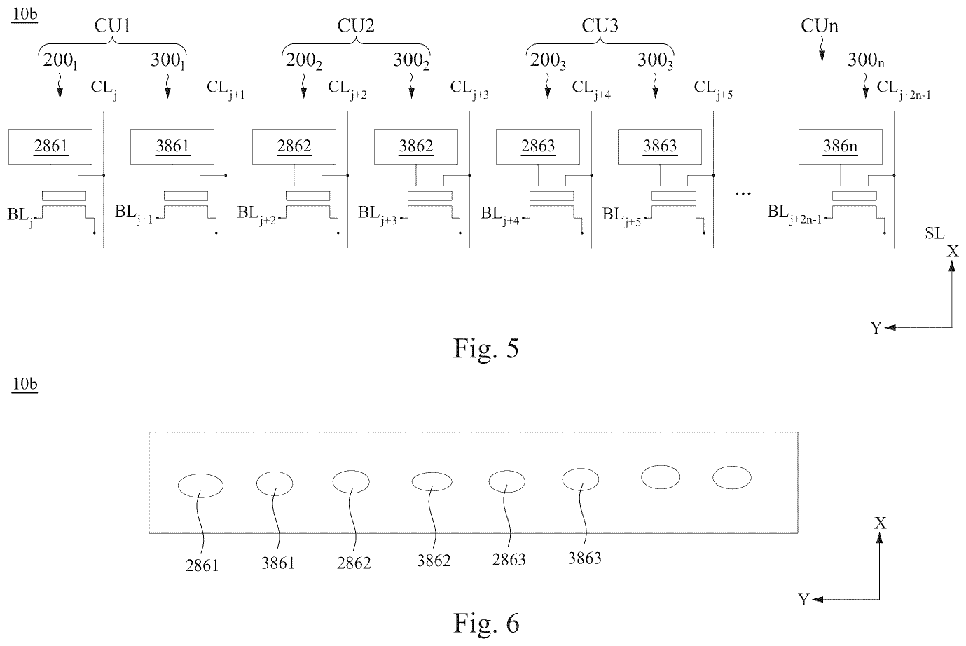

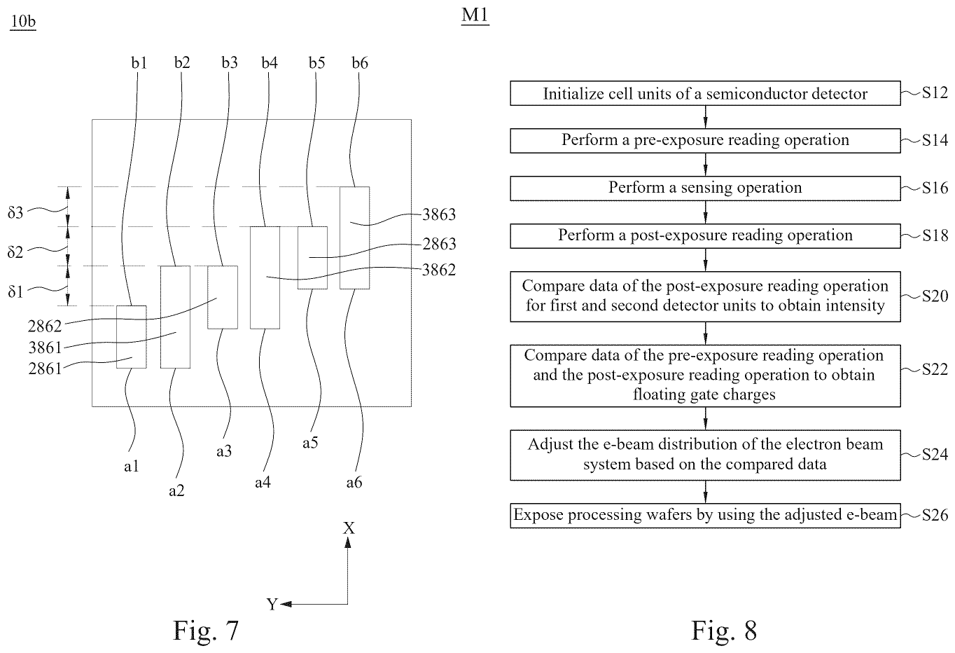

FIG. 5 is a schematic circuit diagram illustrating a semiconductor detector 10b according to some embodiments of the present disclosure. In some embodiments, the semiconductor detector 10b includes a plurality pairs of the cell units CU of FIG. 1 (which are denoted as cell units CU1, CU2, CU3, . . . , CUn in FIG. 5). FIG. 6 is a schematic partial top view of the semiconductor detector 10b in accordance with some embodiments, and FIG. 7 is another schematic partial top view of the semiconductor detector 10b in accordance with some embodiments. As shown in FIG. 5, the pairs of the cell units CU1-CUn are arranged in the Y direction and share the same source line SL. The sensing pads 2861, 3861, 2862, 3862, 2863, 3863, . . . , and 386n of the semiconductor detector 10b are arranged in the Y direction in sequence as shown in FIGS. 6 and 7. In some embodiments, the pitch of the sensing pads 2861, 2862, 2863, . . . , and 3861, 3862, 3863, . . . , 386n may be on the order of micrometers. The sensing pads 2861, 2862, 2863, . . . , and 3861, 3862, 3863, . . . , 386n form a one-direction line-offset sensing nodes, such that the semiconductor detector 10b can be referred to as a line-offset detector array (LODA). The semiconductor detector 10b further includes column lines CLⱼ, CLⱼ₊₁, CLⱼ₊₂, CLⱼ₊₃, CLⱼ₊₄, CLⱼ₊₅, . . . , and CLⱼ₊₂ₙ₋₁, and bit lines BLⱼ, BLⱼ₊₁, BLⱼ₊₂, BLⱼ₊₃, BLⱼ₊₄, BLⱼ₊₅, . . . , and BLⱼ₊₂ₙ₋₁. Each of the recording units (e.g., 200₁, 300₁, 200₂, 300₂, 200₃, 300₃, . . . 300₃) may be referred to as a pixel.

In FIGS. 5 and 7, the sensing pads 2861 and 3861 of the cell unit CU1 have a length difference (or distance) δ1. By comparing the sensing signals of the first recording unit 200₁ and the second recording unit 300₁, the intensity of e-beam light in the distance δ1 can be read. Similarly, the sensing pads 2862 and 3862 of the cell unit CU2 have a length difference (or distance) δ2. By comparing the sensing signals of the first recording unit 200₂ and the second recording unit 300₂, the intensity of e-beam light in the distance δ2 can be read. Also, the sensing pads 2863 and 3863 of the cell unit CU3 have a length difference (or distance) δ3. By comparing the sensing signals of the first recording unit 200₃ and the second recording unit 300₃, the intensity of e-beam light in the distance δ3 can be read. Since the distances δ1-δ3 are nanometer orders, the semiconductor detector 10b have a resolution on a nanometer scale even though the sizes of the sensing pads of the semiconductor detector 10a are on a micrometer scale. The distances δ1-δ3 have the same value or different values.

In FIG. 7, the sensing pad 2861 has opposite ends a1 and b1 in the X direction, the sensing pad 3861 has opposite ends a2 and b2 in the X direction, the sensing pad 2862 has opposite ends a3 and b3 in the X direction, the sensing pad 3862 has opposite ends a4 and b4 in the X direction, the sensing pad 2863 has opposite ends a5 and b5 in the X direction, and the sensing pad 3863 has opposite ends a6 and b6 in the X direction. The end a1 is substantially aligned with the end a2 in the Y direction, and the end b1 is misaligned with the end b2 in the Y direction. The end a2 is misaligned with the end a3 in the Y direction, and the end b2 is substantially aligned with the end b3 in the Y direction. The end a3 is substantially aligned with the end a4 in the Y direction, and the end b3 is misaligned with the end b4 in the Y direction. The end a4 is misaligned with the end a5 in the Y direction, and the end b4 is substantially aligned with the end b5 in the Y direction. The end a5 is substantially aligned with the end a6 in the Y direction, and the end b5 is misaligned with the end b6 in the Y direction.

FIG. 8 is a flowchart of a method M1 for in-situ detecting light uniformity of e-beam according to aspects of the present disclosure in various embodiments. The method M1 is merely an example and is not intended to limit the present disclosure beyond what is explicitly recited in the claims. Additional operations can be provided before, during, and after the method M1, and some operations described can be replaced, eliminated, or moved around for additional embodiments of the process. For clarity and ease of explanation, some elements of the figures have been simplified.

Various operations of the method M1 are discussed in association with cross-section diagrams FIGS. 1-7. Throughout the various views and illustrative embodiments, like reference numbers are used to designate like elements. In operation S12 of FIG. 8, cell units of a semiconductor detector are initialized. For example, each of the gate structures 240 and 340 of the first and second recording units 200 and 300 is performed with the programming process as mentioned above. That is, the electrons are injected into the gate structures 240 and 340 of the first and second recording units 200 and 300. With the programming process, the gate structures 240 and 340 of the first and second recording units 200 and 300 may be at substantially the same electric potential after the initialization process. Alternatively, each of the gate structures 240 and 340 of the first and second recording units 200 and 300 is performed with the erasing process as mentioned above. That is, the electrons are extracted out of the gate structures 240 and 340 of the first and second recording units 200 and 300. With the erasing process, the gate structures 240 and 340 of the first and second recording units 200 and 300 may be substantially free of electrons after the initialization (erasing) process.

In operation S14 of FIG. 8, a pre-exposure reading operation is performed. For example, an in-line wafer acceptance test (WAT) is performed on product wafers which are going to carry on exposure processes. The wafer acceptance test includes numerous testing items and is a part of IC fabrication process. The wafer acceptance test is used to determine product quality. During the wafer acceptance test, the semiconductor detector 10a in FIG. 1 or the semiconductor detector 10b in FIG. 5 is initialized and then the data of the gate structures 240 and 340 of the first and second recording units 200 and 300 is read by performing the process described in the reading state as mentioned above.

FIG. 9 is a schematic circuit diagram of a semiconductor device including a semiconductor detector 10b in FIG. 5 in accordance with some embodiments. The semiconductor device includes a decoder 20, a level shifter 30, the semiconductor detector 10b, and a multiplexer 40. The level shifter 30 is electrically coupled to the decoder 20 and the semiconductor detector 10b, and the semiconductor detector 10b is electrically coupled to the level shifter 30 and the multiplexer 40. The semiconductor detector 10b may be a NOR-type detector array. The decoder 20 is configured to sweep electric potentials to the column lines CLⱼ to CLⱼ₊₂ₙ₋₁. If n=32 (that is, 64 column lines), the decoder 20 may be a 6 to 64 decoder. The level shifter 30 is configured to raise the value of the input electric potentials coming from the decoder 20. The multiplexer 40 is configured to select specific bit line during electrical readout.

In operation S16 of FIG. 8, a sensing operation is performed to the semiconductor detector. In some embodiments, the semiconductor detector 10a or 10b is positioned on a wafer stage of an exposure apparatus. An electron source of an electron beam system is turned on, and an electron beam emitted from the electron source is incident or impinges or illuminates or projects on the semiconductor detector 10a or 10b. The sensing pad structures 280 and 380 sense the e-beam, and amounts of the electrons in the gate structures 240 and 340 are changed. The sensing operation is described in the sensing state as mentioned above.

In operation S18 of FIG. 8, a post-exposure reading operation is performed. For example, another wafer acceptance test (WAT) is performed on the semiconductor detector 10a or 10b. During the wafer acceptance test, the data of the gate structures 240 and 340 of the first and second recording units 200 and 300 of the semiconductor detector 10a or 10b is read again by performing the process described in the reading state and using the circuit illustrated in FIG. 9 as mentioned above.

In operation S20 of FIG. 8, data of the pre-exposure reading operation and the post-exposure reading operation are compared to obtain floating gate charges. Specifically, the data of the post-exposure reading operation is compared with the data of the pre-exposure reading operation so as to obtain the charges stored in the gate structures 240 and 340 during the exposure process.

In operation S22 of FIG. 8, data of the floating gate charges of first and second detector units are compared to obtain intensity. Specifically, by comparison the data (i.e., the induced charge amount Q_{FG1}, Q_{FG2}, and Q_{FG3} of the first and second detector units, the electron variation of each floating gate can be determined, and the corresponding spatial e-beam intensity can be obtained. The details for the operations S18-S22 are described in FIGS. 10A-10C.

FIG. 10A is a perspective view of sensing pads 2861, 3861, 2862, and 3862 in accordance with some embodiments, FIG. 10B is amounts of floating gate charge (Q_{FG}) corresponding to the sensing pads 2861, 3861, 2862, and 3862 in the post-exposure reading, and FIG. 10C is a spectrum of differential signals in the X direction. As shown in FIG. 10B, after the operation S20, the floating gate signals corresponding to the sensing pads 2861 and 3861 are recorded as the curve S1. The curve S1 shows that the floating gate (e.g., the gate structure 240 in FIG. 1) corresponding to the sensing pad 2861 has an induced charge amount Q_{FG1} induced during the exposure process, and the floating gate (e.g., the gate structure 340 in FIG. 1) corresponding to the sensing pad 3861 has an induced charge amount Q_{FG2} induced during the exposure process. The differential signal Q_{D1} between the induced charge amounts Q_{FG1} and Q_{FG2} is illustrated in FIG. 10C. Similarly, the curve S2 shows that the floating gate corresponding to the sensing pad 2862 has an induced charge amount Q_{FG2} induced during the exposure process, and the floating gate corresponding to the sensing pad 3862 has an induced charge amount Q_{FG3} induced during the exposure process. The differential signal Q_{D2} between the induced charge amounts Q_{FG2} and Q_{FG3} is also illustrated in FIG. 10C.

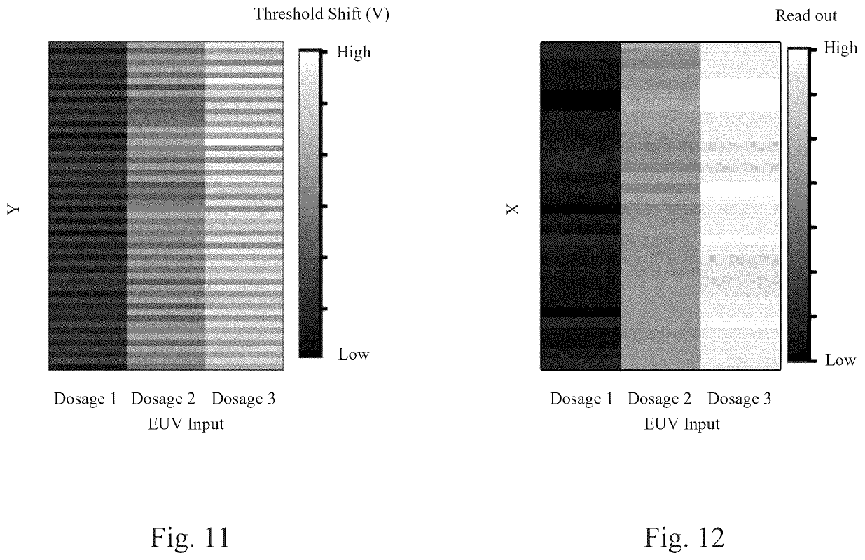

FIG. 11 is an experimental mapping image of threshold voltage shifts of the recording units under different EUV exposure inputs, and FIG. 12 is a mapping image of readout EUV dosage distribution in the X direction under different EUV exposure inputs. In FIG. 11, the experimental threshold voltage shift (corresponding to the floating gate charge as shown in FIG. 10B) for every recording unit (which are arranged in the Y direction) are read. Further, the semiconductor detector 10b are exposed under different EUV exposure dosages (i.e., Dosage 1, Dosage 2, and Dosage 3, where Dosage 3>Dosage 2>Dosage 1). As shown in FIG. 11, the resulting differential signals (Q_{D1} and Q_{D2} as shown in FIG. 10B and corresponding to the threshold voltage shift values) increases with the increasing EUV exposure inputs. Further, the data of the threshold voltage shifts can be converted to readout EUV dosage distribution as shown in FIG. 12. In FIG. 12, the EUV dosage distribution in the X direction is derived, and the spatial resolution is determined by the value of the distance δ (which can be scaled down to nanometer orders).

In operation S24 of FIG. 8, the e-beam distribution of the electron beam system is adjusted based on the compared data. Specifically, the spatial distribution of the e-beam of the semiconductor detector is obtained in the operation S22. If the spatial distribution is not desired (such as non-uniform), parameters of the electron beam system are tuned to form an e-beam having more uniform spatial distribution. That is, the post-exposure reading can be timely feedback to the optimization of the electron beam system.

In operation S26 of FIG. 8, product wafers are exposed by using the adjusted e-beam. For example, the product wafers can be disposed on a wafer stage of the electron beam system. The product wafers each include a photoresist, which can be exposed by the adjusted e-beam. The photoresist can then be developed and a patterned photoresist is formed. With the embodiments of the method M1, the patterning quality of the photoresists is improved.

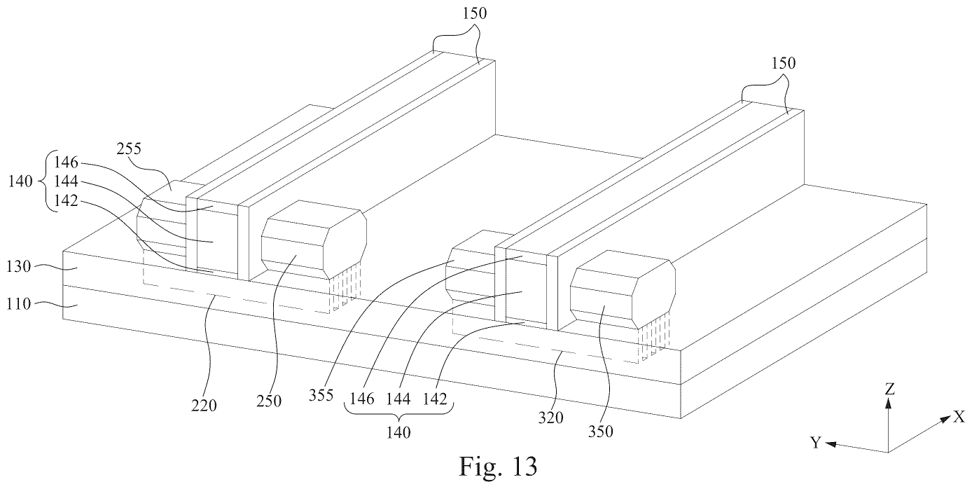

FIGS. 13-16 illustrate a method for manufacturing the semiconductor detector 10a at various stages in accordance with some embodiments of the present disclosure. In addition to the semiconductor detector, FIGS. 13-16 depict X-axis, Y-axis, and Z-axis directions. As described below, the manufacturing process of the semiconductor detector 10a (and 10b) can be compatibility with CMOS logic process. Reference is made to FIG. 13. A substrate 110 is provided. In some embodiments, the substrate 110 is made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 110 may include an epitaxial layer (epi-layer), which may be strained for performance enhancement, and/or may include a silicon-on-insulator (SOI) structure.

One or more semiconductor fins 220 and 320 are formed on the substrate 110. The semiconductor fins 220 and 320 may be formed using, for example, a patterning process to form trenches such that trenches are formed between adjacent semiconductor fins 220 and 320. The semiconductor fins 220 and 320 will be used to form FinFETs. It is understood that four semiconductor fins 220 and 320 are illustrated for purposes of illustration, but other embodiments may include any number of semiconductor fins. In some embodiments, one or more dummy semiconductor fins are formed adjacent to the semiconductor fins 220 and/or 320.

Isolation structures 130, such as shallow trench isolations (STI), are disposed over the substrate 110. The isolation structures 130 can be equivalently referred to as an isolation insulating layer in some embodiments. The isolation structures 130 may be made of suitable dielectric materials such as silicon oxide, silicon nitride, silicon oxynitride, fluorine-doped silicate glass (FSG), low-k dielectrics such as carbon doped oxides, extremely low-k dielectrics such as porous carbon doped silicon dioxide, a polymer such as polyimide, combinations of these, or the like. In some embodiments, the isolation structures 130 are formed through a process such as CVD, flowable CVD (FCVD), or a spin-on-glass process, although any acceptable process may be utilized. Subsequently, portions of the isolation structures 130 extending over the top surfaces of the semiconductor fins 220 and 320, are removed using, for example, an etching back process, chemical mechanical polishing (CMP), or the like. The isolation structures 130 are then recessed to expose an upper portion of the semiconductor fin 220 and 320. In some embodiments, the isolation structures 130 are recessed using a single etch processes, or multiple etch processes. In some embodiments in which the isolation structures 130 is made of silicon oxide, the etch process may be, for example, a dry etch, a chemical etch, or a wet cleaning process. For example, the chemical etch may employ fluorine-containing chemical such as dilute hydrofluoric (dHF) acid.

After the semiconductor fins 220, 320 and the isolation structures 130 are formed, dummy gate structures 140 are formed over the substrate 110 and at least partially disposed over the semiconductor fins 220 or 320. Dummy gate formation operation first forms a dummy gate dielectric layer over the semiconductor fins 220 and 320. Subsequently, a dummy gate electrode layer and a hard mask which may include multiple layers (e.g., an oxide layer and a nitride layer) are formed over the dummy gate dielectric layer. The hard mask is then patterned to be a mask layer 146, followed by patterning the dummy gate electrode layer to be a dummy gate electrode 144 by using the mask layer 146 as an etch mask. In some embodiments, after patterning the dummy gate electrode layer, the dummy gate dielectric layer is removed from the source/drain regions of the semiconductor fins 220, 320 and to be a dummy gate dielectric layer 142. The etch process may include a wet etch, a dry etch, and/or combinations thereof.

After formation of the dummy gate structures 140 is completed, gate spacers 150 are formed on sidewalls of the dummy gate structures 140. In some embodiments of the gate spacer formation operations, a spacer material layer is deposited on the substrate 110. The spacer material layer may be a conformal layer that is subsequently etched back to form the gate spacers 150. In some embodiments, the spacer material layer includes multiple layers, such as a first spacer layer and a second spacer layer formed over the first spacer layer. The first and second spacer layers each are made of a suitable material such as silicon oxide, silicon nitride, silicon carbide, silicon oxynitride, SiCN, silicon oxycarbide, SiOCN, and/or combinations thereof. By way of example and not limitation, the gate spacers 150 may be formed by depositing dielectric materials over the dummy gate structure 140 using processes such as, an ALD process, a PEALD (plasma enhanced ALD) process, a PECVD process, a subatmospheric CVD (SACVD) process, or other suitable process. An anisotropic etching process is then performed on the gate spacers 150 to expose portions of the semiconductor fins 220 and 320 not covered by the dummy gate structures 140.

After the formation of the gate spacers 150 is completed, source/drain epitaxial structures 250 and 255 are formed on source/drain regions of the semiconductor fins 220 that are not covered by the dummy gate structures 140 and the gate spacers 150, while source/drain epitaxial structures 350 and 355 are formed on source/drain regions of the semiconductor fins 320 that are not covered by the dummy gate structures 140 and the gate spacers 150. In some embodiments, formation of the source/drain epitaxial structures 250, 255, 350, and 355 includes recessing source/drain regions of the semiconductor fins 220 and 320, followed by epitaxially growing semiconductor materials in the recessed source/drain regions of the semiconductor fins 220 and 320.

In some embodiments, the source/drain epitaxial structures 250, 255, 350, and 355 include Ge, Si, GaAs, AlGaAs, SiGe, GaAsP, SiP, or other suitable material. The source/drain epitaxial structures 250, 255, 350, and 355 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 250, 255, 350, and 355 are not in-situ doped, an implantation process (i.e., a junction implant process) is performed to dope the source/drain epitaxial structures 250, 255, 350, and 355.

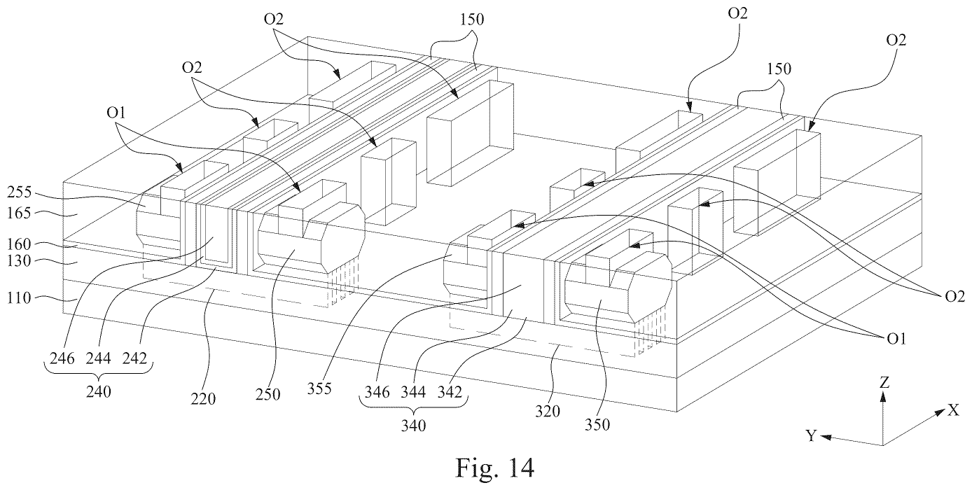

Reference is made to FIG. 14. An interlayer dielectric (ILD) layer 165 is formed on the substrate 110. In some embodiments, a contact etch stop layer (CESL) 160 is also formed prior to forming the ILD layer 165. For clarity, the structures covered by the ILD layer 165 and the CESL 160 are illustrated in solid lines. In some embodiments, the CESL 160 includes a silicon nitride layer, a silicon oxynitride layer, and/or other suitable materials having a different etch selectivity than the ILD layer 165. The CESL 160 may be formed by plasma-enhanced chemical vapor deposition (PECVD) process and/or other suitable deposition or oxidation processes. In some embodiments, the ILD layer 165 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 160. The ILD layer 165 may be deposited by a subatmospheric CVD (SACVD) process, a flowable CVD process, or other suitable deposition technique. In some embodiments, after formation of the ILD layer 165, the wafer may be subject to a high thermal budget process to anneal the ILD layer 165.

In some examples, after forming the ILD layer 165, a planarization process may be performed to remove excessive materials of the ILD layer 165. For example, a planarization process includes a chemical mechanical planarization (CMP) process which removes portions of the ILD layer 165 (and the CESL 160, if present) overlying the dummy gate structure 140. In some embodiments, the CMP process also removes the mask layer 146 (as shown in FIG. 13) and exposes the dummy gate electrode 144.

The dummy gate electrode 144 and the dummy gate dielectric layer 142 (see FIG. 13) are then removed, resulting in gate trenches between the gate spacers 150. Thereafter, replacement gate structures 240 and 340 are formed in the gate trenches. The gate structures 240 and 340 may be the final gates of FinFETs. The final gate structure may be a high-k/metal gate stack, however other compositions are possible. In various embodiments, the (high-k/metal) gate structures 240 and 340 each includes a gate dielectric layer 242 (342) lining the gate trench and a gate electrode over the gate dielectric layer 242 (342). The gate electrode may include a work function metal layer 244 (344 ) formed over the gate dielectric layer 242 (342) and a fill metal 246 (346) formed over the work function metal layer 244 (344) and filling a remainder of gate trenches. The gate dielectric layer 242 (342) includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (~3.9). The work function metal layer 244 (344) and/or fill metal 246 (346) used within the high-k/metal gate structures 240 (340) may include a metal, metal alloy, or metal silicide. Formation of the high-k/metal gate structures 240 (340) may include multiple deposition processes to form various gate materials, one or more liner layers, and one or more CMP processes to remove excessive gate materials.

One or more etching processes are performed to form contact openings O1 and O2 extending though the ILD layer 165 to expose the source/drain epitaxial structures 250, 255, 350, 355 or the isolation structures 130. For example, the contact openings O1 respectively expose the source/drain epitaxial structures 250, 255, 350, or 355, and the contact openings O2 expose the isolation structures 130.

Reference is made to FIG. 15. Reading contacts 260, 360, sensing contacts 270, 370 are respectively formed in the contact openings O2, and source/drain contacts 290, 295, 390, and 395 are respectively formed in the contact openings O1. Formation of the contacts includes, by way of example and not limitation, depositing one or more conductive materials overfilling the contact openings O1 and O2 such that the conductive materials are in contact with the isolation structure 130, and then performing a CMP process to remove excessive conductive materials outside the contact openings O1 and O2.

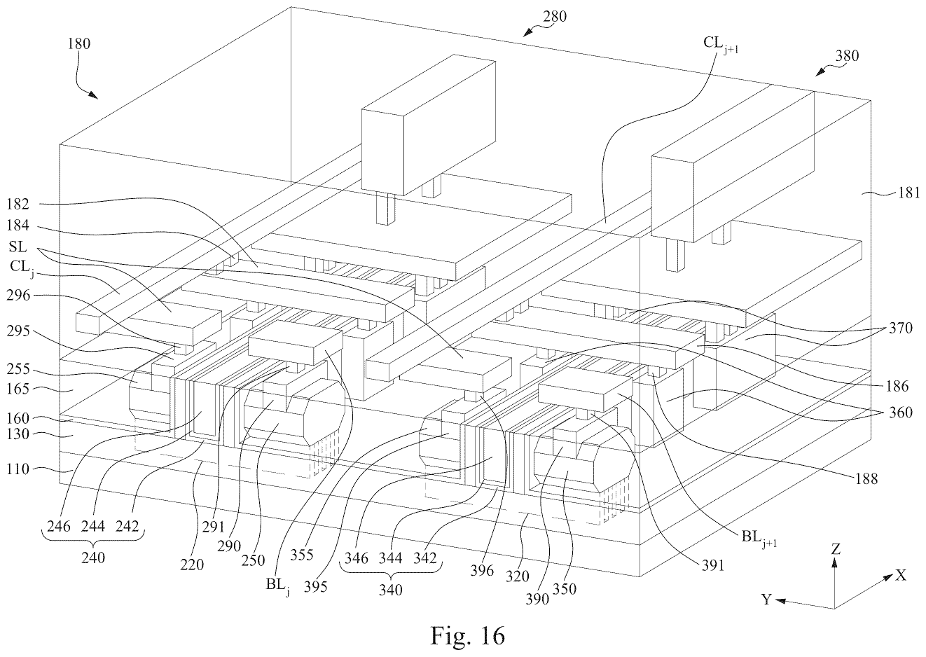

Reference is made to FIGS. 15 and 16. A multilayer interconnect (MLI) structure 180 is formed over the structure of FIG. 15. The interconnect structure 180 includes the sensing pad structures 280 and 380. The interconnect structure 180 further includes the conductive lines 182, 186, the conductive vias 184, 188, 291, 296, 391, 396, the column lines CLⱼ and CLⱼ₊₁, the bit lines BLⱼ and BLⱼ₊₁, and the source line SL. The sensing pad structures 280 and 380, the conductive lines 182, 186, the conductive vias 184, 188, 291, 296, 391, 396, the column lines CLⱼ and CLⱼ₊₁, the bit lines BLⱼ and BLⱼ₊₁, and the source line SL can be formed using, for example, a single damascene process, a dual damascene process, the like, or combinations thereof and may include metal materials such as copper, aluminum, tungsten, combinations thereof, or the like.

The interconnect structure 180 further includes a plurality of inter-metal dielectric (IMD) layers 181 between different levels of the conductive lines and the condictive vias. The IMD layers 181 may include low-k dielectric materials having k values, for example, lower than about 4.0 or even 2.0 disposed between such conductive features. In some embodiments, the IMD layers 181 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. For clarity, the structures covered by the IMD layers 181 are illustrated in solid lines.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the spatial resolution of the cell unit of the semiconductor detector can achieve nanometer precision when employing micrometer-sized structures structure as sensing pads. Further, the sensing (recording) operation of the semiconductor detector is battery-less and powerless. The manufacturing process of the semiconductor detector is compatibility with CMOS logic process.

According to some embodiments, a device includes a substrate, a first recording unit, and a second recording unit. The first recording unit is over the substrate and includes a first active region over the substrate, a first gate structure over the first active region, a first sensing contact adjacent to the first gate structure, and a first sensing pad over the first sensing contact and electrically connected to the first sensing contact. The second recording unit is over the substrate and includes a second active region over the substrate, a second gate structure over the second active region, a second sensing contact adjacent to the second gate structure, and a second sensing pad over the second sensing contact and electrically connected to the second sensing contact. The first recording unit and the second recording unit are arranged in a first direction, and the second sensing pad has a length greater than a length of the first sensing pad in a second direction substantially perpendicular to the first direction.

According to some embodiments, a method includes forming an isolation structure over a substrate to define a first active region and a second active region therein. A first gate structure is formed over the first active region and a second gate structure is formed over the second active region. A first sensing contact is formed over the isolation structure and adjacent to the first gate structure. A second sensing contact is formed over the isolation structure and adjacent to the second gate structure. A first sensing pad is formed over the first gate structure and is electrically connected to the first sensing contact. A second sensing pad is formed over the second gate structure and is electrically connected to the second sensing contact. The first sensing pad and the second sensing pad are arranged in a first direction, and the second sensing pad has a length greater than a length of the first sensing pad.

According to some embodiments, a method includes initializing an electrical potential of a first gate structure and a second gate structure of a semiconductor detector. The semiconductor detector includes a first recording unit and a second recording unit. The first recording unit includes the first gate structure over a first semiconductor fin, a first sensing contact adjacent to the first gate structure, and a first sensing pad over and electrically connected to the first sensing contact. The second recording unit includes the second gate structure over a second semiconductor fin, a second sensing contact adjacent to the second gate structure, and a second sensing pad over and electrically connected to the second sensing contact. The first sensing pad and the second sensing pad have different lengths. The method further includes projecting an e-beam light to the first sensing pad and the second sensing pad of the semiconductor detector after initializing the electrical potential of the first gate structure and the second gate structure of the semiconductor detector. Floating gate charges of the first gate structure and the second gate structure are obtained induced by the e-beam light. Data of the floating gate charges of the first gate structure and the second gate structure are compared. An intensity of the e-beam light is adjusted based on the compared data of the floating gate charges of the first gate structure and the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a substrate;
a first recording unit over the substrate and comprising:
a first active region over the substrate;
a first gate structure over the first active region;
a first sensing contact adjacent to the first gate structure; and
a first sensing pad over the first sensing contact and electrically connected to the first sensing contact; and
a second recording unit over the substrate and comprising:
a second active region over the substrate;
a second gate structure over the second active region;
a second sensing contact adjacent to the second gate structure; and
a second sensing pad over the second sensing contact and electrically connected to the second sensing contact, wherein the first recording unit and the second recording unit are arranged in a first direction, and the second sensing pad has a length greater than a length of the first sensing pad in a second direction substantially perpendicular to the first direction.

2. The device of claim 1, wherein the first sensing pad has a first end and a second end opposite to the first end in a top view, and the second sensing pad has a third end and a fourth end opposite to the third end in the top view, the first end is substantially aligned with the third end in the first direction, and the second end is misaligned with the fourth end in the first direction.

3. The device of claim 1, wherein the length of the second sensing pad is greater than the length of the first sensing pad in the second direction by a distance in a range of about 28 nm to about 50 μm.

4. The device of claim 1, wherein the length of the first sensing pad is in a range of about 0.1 μm to about 70 μm.

5. The device of claim 1, further comprising an interconnect structure over the first gate structure and the second gate structure, wherein the first sensing pad is at a topmost level of the interconnect structure.

6. The device of claim 1, wherein the first recording unit further comprises a reading contact between the first sensing contact and the first active region.

7. The device of claim 1, further comprising:
a first bit line electrically connected to a first source/drain epitaxial structure over the first active region;
a second bit line electrically connected to a third source/drain epitaxial structure over the second active region; and
a source line electrically connected to a second source/drain epitaxial structure over the first active region and a fourth source/drain epitaxial structure over the second active region.

8. The device of claim 1, further comprising:
a third recording unit over the substrate and comprising a third sensing pad; and
a fourth recording unit over the substrate and comprising a fourth sensing pad, wherein the first sensing pad, the second sensing pad, the third sensing pad, and the fourth sensing pad are arranged in the first direction in sequence.

9. The device of claim 8, wherein the third sensing pad has a fifth end and a sixth end opposite to the fifth end in a top view, the fifth end is misaligned with the third end in the first direction, and the sixth end is substantially aligned with the fourth end in the first direction.

10. The device of claim 9, wherein the fourth sensing pad has a seventh end and an eighth end opposite to the seventh end in the top view, the seventh end is substantially aligned with the fifth end in the first direction, and the eighth end is misaligned with the sixth end in the first direction.

11. The device of claim 1, wherein the first gate structure is a floating gate.

12. A method comprising:
forming an isolation structure over a substrate to define a first active region and a second active region therein;
forming a first gate structure over the first active region and a second gate structure over the second active region;
forming a first sensing contact over the isolation structure and adjacent to the first gate structure;
forming a second sensing contact over the isolation structure and adjacent to the second gate structure;
forming a first sensing pad over the first gate structure and electrically connected to the first sensing contact; and
forming a second sensing pad over the second gate structure and electrically connected to the second sensing contact, wherein the first sensing pad and the second sensing pad are arranged in a first direction, and the second sensing pad has a length greater than a length of the first sensing pad.

13. The method of claim 12, further comprising:
forming a first reading contact over the isolation structure, adjacent to the first gate structure, and between the first sensing contact and the first active region; and
forming a second reading contact over the isolation structure, adjacent to the second gate structure, and between the second sensing contact and the second active region.

14. The method of claim 12, further comprising:
forming a first bit line over the first active region and electrically connected to the first active region; and
forming a second bit line over the second active region and electrically connected to the second active region.

15. The method of claim 12, further comprising:
forming a source line over the first active region and the second active region and electrically connected to the first active region and the second active region.

16. The method of claim 12, wherein the first sensing pad has a first end and a second end opposite to the first end in a top view, and the second sensing pad has a third end and a fourth end opposite to the third end in the top view, the first end is substantially aligned with the third end in the first direction, and the second end is misaligned with the fourth end in the first direction.

17. A method, comprising:
initializing an electrical potential of a first gate structure and a second gate structure of a semiconductor detector, wherein the semiconductor detector comprises:
a first recording unit comprising:
the first gate structure over a first semiconductor fin;
a first sensing contact adjacent to the first gate structure; and
a first sensing pad over and electrically connected to the first sensing contact; and
a second recording unit comprising:
the second gate structure over a second semiconductor fin;
a second sensing contact adjacent to the second gate structure; and
a second sensing pad over and electrically connected to the second sensing contact, wherein the first sensing pad and the second sensing pad have different lengths;
projecting an e-beam light to the first sensing pad and the second sensing pad of the semiconductor detector after initializing the electrical potential of the first gate structure and the second gate structure of the semiconductor detector;
obtaining floating gate charges of the first gate structure and the second gate structure induced by the e-beam light;
comparing data of the floating gate charges of the first gate structure and the second gate structure; and
adjusting an intensity of the e-beam light based on the compared data of the floating gate charges of the first gate structure and the second gate structure.

18. The method of claim 17, wherein obtaining floating gate charges of the first gate structure and the second gate structure induced by the e-beam light comprises:
performing a pre-exposure reading operation on the semiconductor detector prior to projecting the e-beam light;
performing a post-exposure reading operation on the semiconductor detector after projecting the e-beam light; and
comparing data of the pre-exposure reading operation with the post-exposure reading operation to obtain the floating gate charges.

19. The method of claim 17, wherein no power is applied to the semiconductor detector during projecting the e-beam light to the first sensing pad and the second sensing pad of the semiconductor detector.

20. The method of claim 17, wherein a length of the second sensing pad is greater than the length of the first sensing pad by a distance in a range of about 28 nm to about 50 μm.
